(19) United States
(12) Patent Application Publication
(10) Pub. No.: US 2026/0136650 A1
(43) Pub. Date: May 14, 2026

(54) SEMICONDUCTOR DEVICE

(71) Applicant: WAVEPIA CO., LTD., Gyeonggi-do (KR)

(72) Inventor: Sang Hun LEE, Hwaseong-si (KR)

(73) Assignee: WAVEPIA CO., LTD., Gyeonggi-do (KR)

(21) Appl. No.: 19/443,379

(22) Filed: Jan. 8, 2026

Related U.S. Application Data
(63) Continuation-in-part of application No. 18/146,528, filed on Dec. 27, 2022, now abandoned.

(30) Foreign Application Priority Data
May 13, 2022 (KR) 10-2022-0058818

(51) Int. Cl. H10D 84/80; H10D 1/47; H10D 62/85; H10D 89/60

(52) U.S. Cl. CPC H10D 84/817; H10D 1/47; H10D 62/8503; H10D 89/911

(57) ABSTRACT

A semiconductor device according to one embodiment of the present invention includes a semiconductor substrate, transistors disposed on the semiconductor substrate, gate pads disposed on the semiconductor substrate and disposed at the outside of the transistors, resistors disposed on the semiconductor substrate and electrically connected to at least one of the gate pads, and upper metal layers disposed on the semiconductor substrate and configured to come into contact with the resistors. At least one of the gate pads is electrically connected to a gate electrode of each of the transistors, the gate pads are spaced apart from each other, and at least one of the resistors is an anti-resonance resistor, which is configured to suppress resonance generated by operation of the transistors, is disposed between two gate pads, and is electrically connected to at least one gate pad of the two gate pads through the upper metal layer.

### CROSS-REFERENCE TO RELATED APPLICATIONS

The present application is a Continuation-in-Part of U.S. patent application Ser. No. 18/146,528, filed on Dec. 27, 2022, which claims priority to and the benefit of Korean Patent Application No. 10-2022-0058818, filed on May 13, 2022. The disclosures of the above-listed applications are hereby incorporated by reference herein in their entirety.

### TECHNICAL FIELD

The present invention relates to a semiconductor device, and more specifically, to a semiconductor device including an anti-resonance resistor.

### RELATED ART

Recently, much attention has been paid to a power amplifier (PA) semiconductor manufacturing technology or monolithic microwave integrated circuit (MMIC) design technology in fields such as electric vehicles, autonomous vehicles, wireless communication including 5G or 6G, satellite communication, high-resolution radar, and the like.

Specifically, various technologies and materials have been developed to transmit and receive data with high output. For example, since gallium nitride (GaN) can operate at a high voltage due to a wide energy gap of 3.4 eV, have high current density and power density, and operate at a high speed, recently, use of a GaN high electron mobility transistor (HEMT) element has rapidly increased as a material for a high-output, high-efficiency, and small-sized power amplifier (PA) element.

However, intervals between transistors become narrower as a semiconductor device is developed to operate at a high speed, to have high output and high efficiency, and to be miniaturized. Accordingly, in a conventional semiconductor device, there is a problem in that each transistor disposed in the semiconductor device generates a resonance effect, and thus RF performance is lowered and a lifespan is shortened.

Further, the conventional semiconductor device has a problem in that heat released from the transistors disposed in the semiconductor device cannot be accurately sensed, and thus performance of the semiconductor device is lowered and the lifespan is shortened.

In addition, a conventional semiconductor device including an anti-resonance function has a problem in that a package of the semiconductor device includes an insulator for preventing resonance therein, and thus manufacturing costs and time increase and the volume increases.

In addition, a conventional semiconductor device including a temperature measurement function has a problem in that an additional process of forming a temperature measurement unit is included or an additional space for disposing the temperature measurement unit is provided, and thus manufacturing costs and time increase and the volume increases.

Meanwhile, the above-described background art is technical information retained for derivation of the present invention or acquired during a derivation process of the present invention by the inventor, and is not necessarily known art disclosed to the general public before application of the present invention.

### Technical Problem

The present invention is directed to providing a semiconductor device in which a configuration which prevents resonance between transistors is disposed, and thus radio frequency (RF) characteristics and a lifespan are improved.

Further, the present invention is directed to providing a semiconductor device which may be monitored to maintain the highest performance by accurately measuring heat released from a plurality of transistors, and of which RF characteristics and a lifespan are improved.

In addition, the present invention is directed to providing a semiconductor device including a configuration capable of performing both an anti-resonance function and a temperature measurement function, thereby reducing a volume and reducing manufacturing costs and time.

Problems of the present invention are not limited to the above-mentioned problems, and other problems which are not mentioned may be apparently understood by those skilled in the art from the following disclosure.

### SUMMARY

In order to solve the above-described problem, a semiconductor device according to one embodiment of the present invention includes a semiconductor substrate, a plurality of transistors disposed on the semiconductor substrate and each including a gate electrode, a source electrode, and a drain electrode, a plurality of gate pads disposed on the semiconductor substrate and disposed at the outside of the plurality of transistors, a plurality of resistors disposed on the semiconductor substrate and electrically connected to at least one of the plurality of gate pads, and a plurality of upper metal layers disposed on the semiconductor substrate and configured to come into contact with the plurality of resistors, wherein at least one of the plurality of gate pads is electrically connected to the gate electrode of each of the plurality of transistors, the plurality of gate pads are spaced apart from each other, and at least one of the plurality of resistors is an anti-resonance resistor, and the anti-resonance resistor is configured to suppress resonance generated by operation of the plurality of transistors, is disposed between two gate pads and is electrically connected to at least one gate pad of the two gate pads through the upper metal layer.

According to another aspect of the present invention, the semiconductor device may further include an active layer disposed between the semiconductor substrate and the transistors, and the active layer may be formed of a compound including Ga and N and may have thermal conductivity.

According to still another aspect of the present invention, the plurality of resistors may be formed as one among thin film resistors and mesa resistors.

According to yet another aspect of the present invention, the semiconductor device may further include at least one temperature measurement pad spaced apart from the plurality of gate pads, and at least one of the plurality of resistors may be a temperature sensing resistor for calculating a temperature change of the plurality of transistors, and the at least one temperature measurement pad may be electrically connected to the temperature sensing resistor through the plurality of upper metal layers, and may be configured to provide a current value or a voltage value of the temperature sensing resistor to a terminal external to the semiconductor device.z

According to yet another aspect of the present invention, the temperature sensing resistor may be the anti-resonance resistor.

According to yet another aspect of the present invention, the semiconductor device may further include an electrically opened floating resistor disposed on the semiconductor substrate, and the floating resistor may be electrically connected to the at least one temperature measurement pad and may be a temperature sensing resistor for calculating a temperature change of the plurality of transistors.

### Advantageous Effects

According to one of solutions of the present invention, since a configuration which prevents resonance between transistors is disposed in a semiconductor device, radio frequency (RF) characteristics and a lifespan can be improved.

Further, according to one of solutions of the present invention, since heat released from a plurality of transistors is accurately measured, a semiconductor device can be monitored so that the highest performance can be maintained, and RF characteristics and a lifespan can be improved.

In addition, according to one of solutions of the present invention, since a configuration capable of performing both an anti-resonance function and a temperature measurement function is disposed in a semiconductor device, a volume of the semiconductor device can be reduced, and manufacturing costs and time of the semiconductor device can be reduced.

Effects which can be acquired from the present invention are not limited to the above-mentioned effects, and other effects which are not mentioned can be clearly understood by those skilled in the art from the following disclosure.

### BRIEF DESCRIPTION OF DRAWINGS

FIG. 1 is a plan view of a semiconductor device according to one embodiment of the present invention.

FIG. 2 is a cross-sectional view taken along dash-dot line II-II′ in FIG. 1.

FIG. 3 is a cross-sectional view taken along dash-dot line III-III′ in FIG. 1.

FIG. 4 is a plan view of a semiconductor device according to another embodiment of the present invention.

FIG. 5 is a cross-sectional view taken along dash-dot line IV-IV′ in FIG. 4.

### DETAILED DESCRIPTION

Advantages and features of the present invention, and a method of achieving them, will become apparent with reference to embodiments which are described in detail in conjunction with the accompanying drawings. However, the present invention is not limited to the embodiments which will be described below and may be implemented in different forms. The embodiments are only provided to completely disclose the present invention and completely convey the scope of the present invention to those skilled in the art, and the present invention is only defined by the disclosed claims.

Since a shape, a size, a ratio, an angle, the number, and the like disclosed in the drawings for describing the embodiment of the present invention are exemplary, the present invention is not limited to the illustrated items. Further, in a description of the present invention, when it is determined that a detailed description for a related known technology may unnecessarily obscure the principle of the present invention, the detailed description will be omitted. When terms ‘include,’ ‘have,’ ‘be formed of,’ and the like mentioned in the present specification are used, other parts may be added unless the term ‘only’ is used. A case in which a component is expressed in a singular form includes a case of including a plural form unless specifically disclosed otherwise.

In interpretation of the components, even when there is no separate explicit description, it is interpreted that an error range is included.

Although first, second, and the like are used to describe various elements or components, these elements or components are not limited by these terms. These terms are only used to distinguish one element or component from another. Accordingly, a first element or component mentioned below may be a second element or component within the spirit of the present invention.

The same reference numeral refers to the same component throughout the specification unless otherwise specified.

Features of the various embodiments of the present invention can be partially or entirely coupled to or combined with each other, and as those skilled in the art may fully understand, may be various interlocked and driven, and the embodiments may be embodied independently of each other, and may also be embodied together in an associative relationship.

Hereinafter, the present invention will be described in detail with reference to the accompanying drawings.

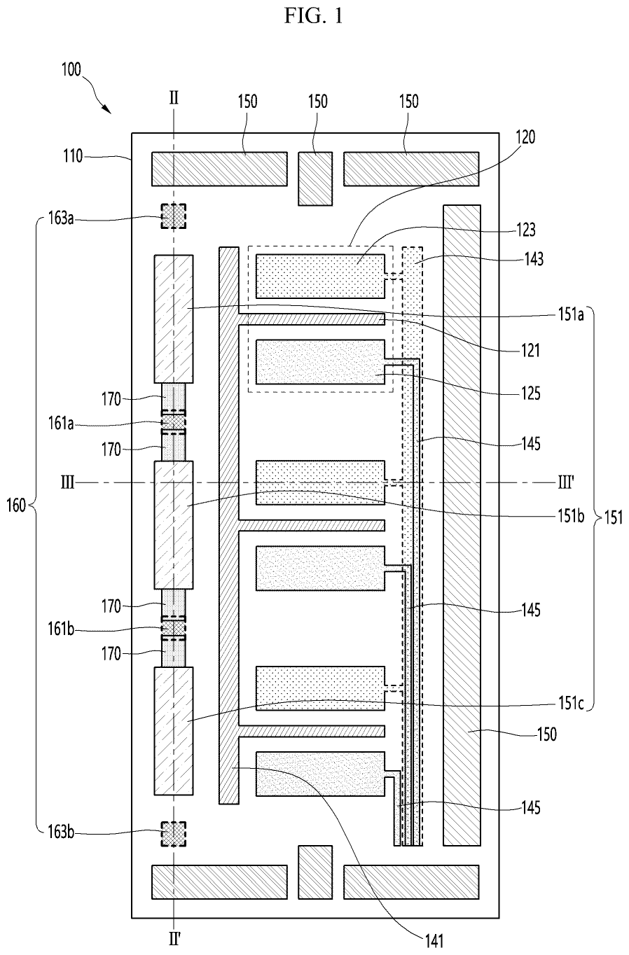

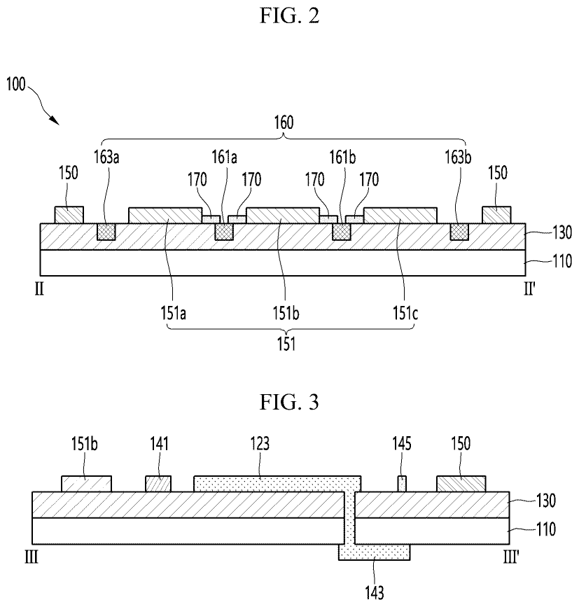

FIG. 1 is a plan view of a semiconductor device according to one embodiment of the present invention, FIG. 2 is a cross-sectional view taken along dash-dot line II-II′ in FIG. 1, and FIG. 3 is a cross-sectional view taken along dash-dot line III-III′ in FIG. 1.

First, referring to FIGS. 1, 2 and 3, a semiconductor device 100 includes a semiconductor substrate 110, a plurality of transistors 120, a plurality of pads 150, a plurality of resistors 160, and a plurality of upper metal layers 170.

Referring to FIGS. 1, 2 and 3, the semiconductor substrate 110 is disposed under an active layer 130. The semiconductor substrate 110 may be formed of various materials such as Si, SiC, Al₂O₃, GaAs, InP, InAs, InSb, and the like. An oxide film insulating layer may be additionally disposed in the semiconductor substrate 110. Further, the semiconductor substrate 110 may be generated through processes such as oxidation, photolithography, etching, thinning, and the like.

Referring to FIG. 1, the plurality of transistors 120 are disposed in a center portion of the semiconductor substrate 110. Each of the transistors 120 includes a gate electrode 121, and a source electrode 123 and a drain electrode 125 disposed at both sides of the gate electrode 121 with the gate electrode 121 as a center.

Referring to FIGS. 1 and 2, the plurality of transistors 120 may be disposed on the active layer 130 and disposed in the center portion of the semiconductor device 100. The arrangement and structure of the transistors 120 have been shown and described as a structure of a metal oxide semiconductor field effect transistor (MOSFET) for convenience of description, but are not limited thereto, and may be replaced with various arrangements and structures of transistors. For example, the transistors 120 may be disposed in a predetermined region on the semiconductor substrate 110 and may have a high electron mobility transistor (HEMT) structure or a structure divided into an upper electrode and a lower electrode. The transistor 120 may amplify a signal or perform a current switch function by adjusting a current flow or a voltage.

In addition, a transistor array means that the plurality of transistors 120 are disposed in the semiconductor device 100 at predetermined intervals or according to predetermined rules. Specifically, since the source electrode 123 and the drain electrode 125 are disposed in parallel with the gate electrode 121 interposed therebetween, a transistor array may be generated as the plurality of transistors 120 are disposed adjacent to each other at predetermined intervals. FIGS. 1 and 2 exemplarily illustrate that the transistor array is formed as 3 transistors 120 are disposed in the center portion of the semiconductor device 100, but the number of transistors 120 constituting the transistor array is not limited thereto, and may be changed without limitation according to various embodiments of the invention.

The plurality of transistors 120 may be designed to have the same electrical characteristics, and the number of transistors 120 and a width and a length of each electrode may be arbitrarily designed. For example, when a current flowing between the source electrode 123 and the drain electrode 125 of one of the plurality of transistors 120 is smaller than a current flowing between the source electrode and the drain electrode of each of the remaining transistors, the width and length of the electrode of one of the transistors 140 may be disposed to be reduced or increased.

Referring to FIG. 1, the plurality of gate electrodes 121 extend from the gate line 141. The gate electrode 121 may be formed of metal. When a voltage is applied to the gate electrodes 121 through gate pads 151, the gate electrodes 121 may control the electrical conductivity of the transistor 120.

Referring to FIG. 1, the source electrodes 123 extend from the source line 143 and the drain electrodes 125 extend from the data line 145. The source electrode 123 and the drain electrode 125 are spaced apart from each other with the gate electrode 121 interposed therebetween. The source electrode 123 and the drain electrode 125 may be formed of metal.

The source electrode 123 and the drain electrode 125 may be composed of the same material. Accordingly, the source electrode 123 and the drain electrode 125 may come into ohmic contact with the active layer 130 which is a semiconductor. Further, since the source electrode 123 and the drain electrode 125 are symmetrical elements, the transistor 120 may operate normally even when positions of the source electrode 123 and the drain electrode 125 are changed.

The plurality of gate electrodes 121, the plurality of source electrodes 123, and the plurality of drain electrodes 125 may be disposed on the semiconductor substrate 110. Specifically, the plurality of gate electrodes 121, the plurality of source electrodes 123, and the plurality of drain electrodes 125 may be disposed on an upper surface of the active layer 130.

Referring to FIGS. 1 and 3, The gate line 141 and the plurality of data lines 145 may be disposed on the semiconductor substrate 110. For example, the gate line 141 and the plurality of data lines 145 may be disposed on the upper surface of the active layer 130. The source line 143 may be disposed on a different layer from the data line 145. For example, the source line 143 may be disposed on a lower surface of the semiconductor substrate 110. In some cases, the source line 143 may be disposed on a lower layer of the active layer 130, or an upper layer of an insulating layer disposed on the data line 145.

The plurality of gate electrodes 121 and the gate line 141 are connected to each other. For example, the plurality of gate electrodes 121 and the gate line 141 disposed on the upper surface of the active layer 130 may be integrally formed. The plurality of drain electrodes 125 and the plurality of data lines 145 may be connected to each other, respectively. For example, the plurality of drain electrodes 125 disposed on the upper surface of the active layer 130 may be integrally formed with different data lines 145. The source electrode 123 is connected to the source line 143. Specifically, the source electrode 123 may be electrically connected to the source line 143 through an electrically conductive material disposed in a via. For example, the source electrode 123 disposed on the upper surface of the active layer 130 may be electrically connected to the source line 143 disposed on a lower surface of the semiconductor substrate 110 through an electrically conductive material disposed inside a TSV penetrating the semiconductor substrate 110 and the active layer 130. In some cases, the source line 143 may be connected to a ground of the semiconductor device 100.

The gate line 141 may be disposed as a line at one side of the center portion of the semiconductor device 100, and the plurality of data lines 145 may be disposed as a line at the other side of the center portion of the semiconductor device 100. The gate line 141 and the data lines 145 may be disposed in parallel to each other.

When a voltage is applied between the source electrode 123 and the drain electrode 125, a drain current may flow, and an amount of drain current may be controlled by the voltage applied between the gate electrode 121 and the source electrode 123. In the above-described case, a linear relationship may be formed between the voltage and the current applied to the drain electrode 125. In this case, the source electrode 123 and the drain electrode 125 may operate like a variable resistor. The source electrode 123 may supply charge carriers to a channel region of the transistor 120, and the drain electrode 125 may absorb the charge carriers.

The gate line 141, the source line 143 and the data lines 145 are only means for efficiently forming the plurality of transistors 120, and thus may be freely disposed according to the properties and configuration of a target semiconductor device 100. In particular, referring to FIG. 1, the source line 143 is illustrated in the form of a line parallel to the data line 145, but this is an exemplary representation that the source line 143 and the data line 145 are disposed on different layers from each other. In some cases, the source line 143 may be disposed at various positions and in various forms on a different layer from the data line 145. For example, the source line 143 may have a form of a ground layer disposed on the lower surface of the semiconductor substrate 110, and may be connected to the plurality of source electrodes 123 through vias.

Referring to FIGS. 2 and 3, the active layer 130 is disposed on the semiconductor substrate 110. For example, the active layer 130 may be disposed on an entire upper surface of the semiconductor substrate 110. Further, the active layer 130 is disposed under the transistors 120, the pads 150, and the upper metal layer 170. In addition, the resistor 160 is disposed in the active layer 130.

The active layer 130 may be formed of various materials according to types of the semiconductor substrate 110 and the transistor 120. The active layer 130 may be formed through a process such as epitaxial growth or the like in which Ga, which is a Group 3 element, N, which is a Group 5 element, and the like are supplied to the semiconductor substrate 110. Accordingly, a material of the active layer 130 may be a compound including the Group 3 and Group 5 elements. For example, the material of the active layer 130 may be AlGaN, GaN, or GaAs. The active layer 130 may have thermal conductivity and may conduct heat generated from the transistors 120 to an external region of the transistor 120.

The active layer 130 may include a doped region and an undoped region. Specifically, the active layer 130 may include a doped region doped with a conductive impurity and an undoped region that is not doped. The doped region may have electrical conductivity, and the undoped region may have insulation properties or may have significantly lower electrical conductivity compared to the doped region. The doped region may include an electrical path necessary for operation of the transistor 120. Specifically, the doped region may include a source region, a drain region, and a channel region. The undoped region may contact the plurality of pads 150, the plurality of resistors 160, and a plurality of wirings. Accordingly, electrical leakage paths through the active layer 130 may not be formed between the undoped region and the plurality of pads 150, the plurality of resistors 160, and the plurality of wirings.

A channel region of the transistor 120 may be formed in the active layer 130. The channel region refers to a region in the transistor 120 where carriers such as electrons or holes may move. The channel region of the transistors 120 is generated in the form of a thin band between the active layer 130 under the source electrodes 123 and the active layer 130 under the drain electrodes 125. The channel region of the transistor 120 may be generated while the carriers move in a partial region of the active layer 130 when a voltage higher than a threshold voltage is applied to the gate electrodes 121 and a voltage is applied to the drain electrodes 125.

In general, since a change in potential generated when a voltage is applied to or disconnected from the gate electrode 121 generates the most heat energy in the transistor 120, a region close to the gate electrode 121 in the channel region of the transistor 120 may be a portion having the highest temperature in the semiconductor device 100.

The pad 150 refers to a portion where an external terminal of the semiconductor device 100 is electrically connected to the semiconductor device 100. Referring to FIGS. 1 and 2, the pads 150 are disposed in the semiconductor substrate 110 and at the outside of at least one transistor 120. The pads are also disposed on the active layer 130. The pads 150 may be formed of metal.

The plurality of pads 150 may be connected to the electrodes of the transistor 120 or the resistor 160 through wirings or the upper metal layer 170. The pad 150 may receive various electrical signals and the like supplied from the outside of the semiconductor device 100 and supply the received electrical signals and the like to the semiconductor device 100. In this case, the gate pads 151, drain pads, or source pads may be disposed on the semiconductor substrate 110. Further, the pad 150 may transmit information about temperature, radio frequency (RF) characteristics, and the like of the semiconductor device 100 to the outside of the semiconductor device 100. In this case, a temperature measurement pad 150 for or an RF measurement pad may be disposed on the semiconductor substrate 110.

Referring to FIG. 1, the gate pads 151 may include three pads 151a, 151b, and 151c. The gate pads 151a, 151b, and 151c are spaced apart from each other. The arrangement positions, number, or shapes of the gate pads 151 are not limited to the arrangement in FIGS. 1 and 2. The gate pads 151 are electrically connected to the gate line 141, and the electrical signals applied to the gate pads 151 from the outside of the semiconductor device 100 are transmitted to the plurality of gate electrodes 121 through the gate line 141.

Referring to FIGS. 1 and 2, the plurality of resistors 160 are disposed at an outer side of the semiconductor substrate 110. Specifically, the plurality of resistors 160 are disposed on the semiconductor substrate 110 in an outer region of the region where the plurality of transistors 120 are disposed. Further, the plurality of resistors 160 are disposed between each of the pads 150 or gate pads 151. In addition, the resistors 160 are spaced apart from the pads 150 or gate pads 151. Specifically, referring to FIG. 2, the resistors 160 are disposed in the active layer 130. The arrangement positions, number, and shapes of the resistors 160 on the semiconductor substrate 110 in a plan view are not limited, and may be changed according to the purpose of the resistors 160 and a surplus space of the semiconductor device 100.

The resistor 160 may be a thin film resistor (TFR) and may be composed of NiCr or TaN. Alternatively, the resistor 160 may be a mesa resistor. Preferably, the resistor 160 may be a thin film resistor.

The plurality of resistors 160 include at least one anti-resonance resistor 161. The anti-resonance resistor 161 is a resistor 160 which prevents a resonance effect of the semiconductor device 100. That is, at least one of the four resistors 160 in FIG. 1 may be a resistor which performs an anti-resonance function. The anti-resonance resistor 161 may be disposed between the gate pads 151. Referring to FIGS. 1 and 2, the plurality of resistors 160 include two anti-resonance resistors 161 and two floating resistors 163. Specifically, the anti-resonance resistor 161 is disposed between two gate pads 151, and the two floating resistors 163 are disposed between the gate pads 151 and both side portions of the semiconductor device 100. For example, a first anti-resonance resistor 161a is disposed between a first gate pad 151a and a second gate pad 151b, and a second anti-resonance resistor 161b is disposed between the second gate pad 151b and a third gate pad 151c.

The anti-resonance resistor 161 is electrically connected to at least one gate pad 151 through the upper metal layer 170. Specifically, both terminals of the anti-resonance resistor 161 may be connected to different gate pads 151 through the plurality of upper metal layers 170. Further, at least one gate pad 151 is electrically connected to at least one transistor 120. Specifically, the gate pad 151 is electrically connected to the gate electrode 121 of the transistor 120. Accordingly, the anti-resonance resistors 161 are electrically connected to the transistors 120.

Parasitic capacitance and parasitic inductance may be formed due to the electrode structure of the transistor 120, metal wirings including the upper metal layer 170, and the plurality of pads 150. The parasitic capacitance and parasitic inductance may form a parasitic LC resonance circuit. For example, the parasitic capacitance formed between the gate electrode 121 and the source electrode 123 or between the gate electrode 121 and the drain electrode 125 of the transistor 120, and the parasitic inductance formed in the metal wiring connecting the gate electrode 121 and the gate pad 151 may form a parasitic LC resonance circuit. In this case, resonance may occur due to the parasitic LC resonance circuit during operation of the transistor 120.

Resonance refers to an effect in which an amplitude of a signal of a specific frequency becomes very large. When the resonance effect occurs in the transistor 120, a very large circulating harmonic current is generated in the transistor 120 and a circuit connected to the transistor 120. Specifically, since the transistor 120 is a nonlinear element, the transistor 120 may generate harmonic components such as second-order, third-order, and fifth-order harmonics in addition to a fundamental frequency of an input signal during operation. When odd harmonics among these harmonic components coincide with a resonance frequency of the parasitic LC resonance circuit, the resonance effect may be amplified, and a very large circulating harmonic current may be generated in the transistor 120 and a circuit connected to the transistor 120. When such an abnormal current occurs, RF performance of the semiconductor device 100 may be reduced or elements disposed inside the semiconductor device 100 may be destroyed. Specifically, odd harmonics among resonant harmonics cause great damage to the circuit.

The anti-resonance resistors 161 suppress the resonance generated in the semiconductor device 100 as at least one transistor 120 operates. Specifically, the anti-resonance resistors 161 may suppress the resonance of the parasitic LC circuit generated in or around the plurality of transistors 120 as the plurality of transistors 120 operate. More specifically, the anti-resonance resistors 161 connected in series with the at least one gate pad 151 may suppress the resonance caused by the parasitic LC circuit generated in the transistor 120 by adding a resistive component to the parasitic LC resonance circuit. That is, the anti-resonance resistors 161 may reduce a quality factor (Q factor) of the resonance circuit to lower selectivity of a resonance peak. In addition, the anti-resonance resistors 161 may dissipate energy of odd harmonic currents as heat through I²R loss in a resonance frequency band, thereby suppressing damage to elements inside the semiconductor device 100 due to the resonance effect. That is, the anti-resonance resistors 161 consume the energy of odd harmonic currents generated in the transistors 120 of the semiconductor device 100. Accordingly, the anti-resonance resistors 161 protect the semiconductor device 100 by suppressing damage to the elements in the semiconductor device 100 due to the resonance effect.

Referring to FIGS. 1 and 2, the floating resistors 163 may be disposed on the semiconductor substrate 110 and disposed at both ends of the semiconductor substrate 110. Specifically, the floating resistors 163 may be disposed between the gate pads 151 and both side portions of the semiconductor device 100 on the semiconductor substrate 110. The floating resistors 163 refer to electrically open resistors 160. The floating resistors 163 are the resistors 160 disposed to design the semiconductor device 100 symmetrically so that those skilled in the art may easily change a size of the semiconductor device 100 in the field of semiconductor design.

Referring to FIGS. 1 and 2, the upper metal layer 170 is disposed in a partial region on the active layer 130. The upper metal layer 170 is disposed to come into contact with a portion of an upper end of the resistor 160. Further, the upper metal layer 170 may be disposed to come into contact with the pad 150. The upper metal layer 170 may be a portion of a barrier metal deposited to prevent contamination of the semiconductor device 100.

The upper metal layer 170 electrically connects the pad 150 and the resistor 160. Accordingly, the upper metal layer 170 may serve as a connection path in which the anti-resonance resistors 161 prevent the resonance of the semiconductor device 100 through the gate pads 151.

According to the above-described embodiment, since the anti-resonance resistor 161 suppress the resonance effect of the transistor 120 and a circuit electrically connected to the transistor 120, the RF characteristics of the semiconductor device 100 may be improved, the semiconductor device 100 may operate more accurately even at high temperature, and a lifespan of the semiconductor device 100 may be increased.

Further, according to the above-described embodiment, since the anti-resonance resistor 161 is formed to be inserted into the active layer 130 in a process of forming the active layer 130, an additional process of disposing the anti-resonance resistor 161 in the semiconductor device 100 need not be added. Accordingly, the manufacturing process time and costs of the semiconductor device 100 may be reduced.

Further, according to the above-described embodiment, since the elements of the semiconductor device 100 are symmetrically disposed, the number of transistors 120 constituting the array of the transistors 120 may be easily adjusted while maintaining the characteristics of the semiconductor device 100.

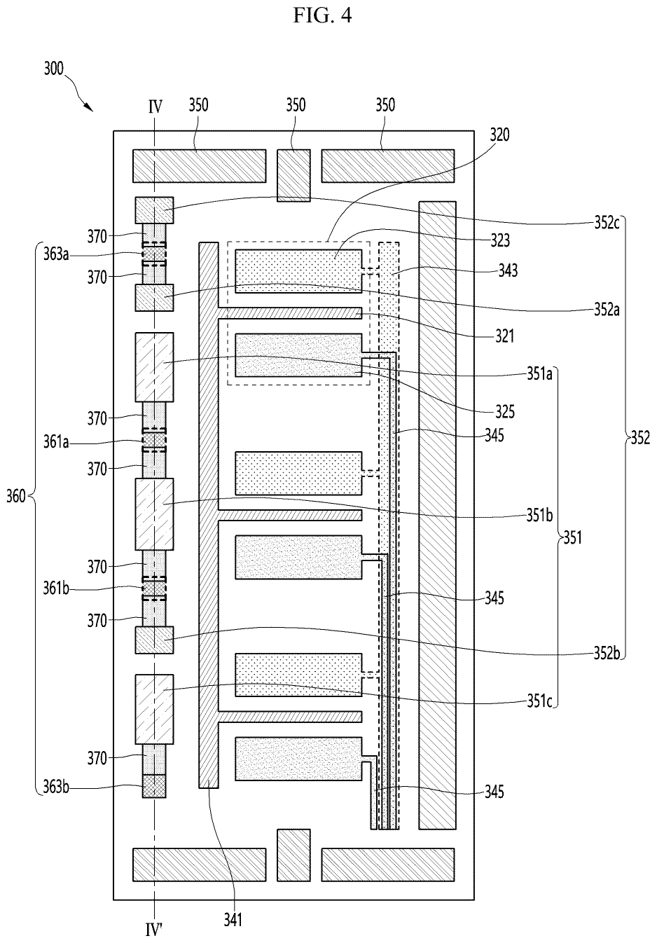

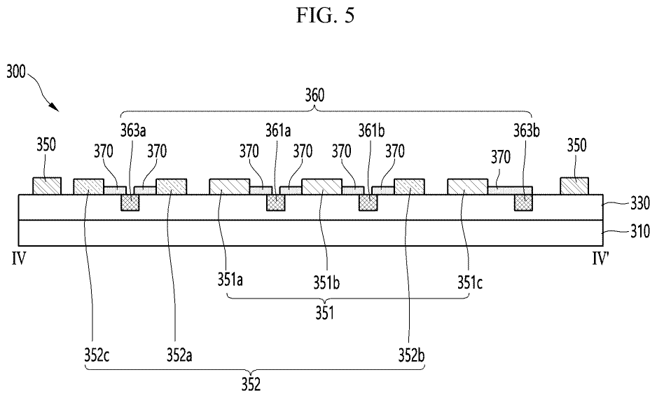

FIG. 4 is a plan view of a semiconductor device according to another embodiment of the present invention, and FIG. 5 is a cross-sectional view taken along dash-dot line IV-IV′ in FIG. 4. The embodiments shown in FIGS. 4 and 5 have substantially the same or corresponding configurations as the embodiment shown in FIGS. 1 and 2 except for temperature measurement pads 352 and temperature sensing resistors 361b and 363a, overlapping descriptions of the configurations described in FIGS. 1 and 2 will be omitted.

Referring to FIGS. 4 and 5, configurations of a plurality of transistors 320 may be substantially the same as configurations of the plurality of transistors 120 of FIGS. 1, 2 and 3.

Specifically, each transistor 320 includes a gate electrode 321, and a source electrode 323 and a drain electrode 325 disposed at both sides of the gate electrode 321 with the gate electrode 321 as a center. The plurality of gate electrodes 321 extend from a gate line 341, the source electrodes 323 extend from a source line 343, and the drain electrodes 325 extend from a data line 345.

Configurations and positional relationships of the gate line 341, the source line 343, and the data line 345 may be substantially the same as configurations and positional relationships of the gate line 141, the source line 143, and the data line 145 of FIGS. 1, 2 and 3. Specifically, the gate line 341 and the data line 345 may be disposed in parallel on an upper surface of the semiconductor substrate 110. The source line 343 may be disposed on a lower surface of the semiconductor substrate 110. The source line 343 disposed on the lower surface of the semiconductor substrate 110 may be electrically connected to the source electrodes 323 through an electrically conductive material disposed inside TSVs penetrating the semiconductor substrate 110 and the active layer 130.

Referring to FIGS. 4 and 5, at least one temperature measurement pad 352 is disposed on an active layer 330. The at least one temperature measurement pad 352 may be spaced apart from gate pads 351. Specifically, the temperature measurement pad 352 may be disposed between gate pads 351, and may be disposed between a gate pad 351 and one end of a semiconductor device 300. For example, the first temperature measurement pad 352a may be disposed between a first gate pad 351a and one end of the semiconductor device 300 adjacent to the first gate pad 351a, and the second temperature measurement pad 352b may be disposed between a second gate pad 351b and a third gate pad 351c. In addition, a third temperature measurement pad 352c may be disposed between the first temperature measurement pad 352a and one end of the semiconductor device 300 adjacent to the first temperature measurement pad 352a. Although FIG. 4 illustrates that the first temperature measurement pad 352a and the third temperature measurement pad 352c are disposed between the first gate pad 351a and one end of the semiconductor device 300 adjacent to the first gate pad 351a, the first temperature measurement pad 352a may be disposed between two gate pads 351 like the second temperature measurement pad 352b. Likewise, the second temperature measurement pad 352b may be disposed between the third gate pad 351c and one end of the semiconductor device 300 adjacent thereto like the first temperature measurement pad 352a. That is, both temperature measurement pads 352 may be disposed between the gate pads 351 or may be disposed between the gate pad 351 and one end of the semiconductor device 300.

Further, each temperature measurement pad 352 comes into contact with an upper metal layer 370. The temperature measurement pad 352 may be connected to one resistor 361b or 363a among a plurality of resistors 360 through the upper metal layer 370. Specifically, the first temperature measurement pad 352a and the third temperature measurement pad 352c may be connected to a first temperature sensing resistor 363a through the upper metal layer 370, and the second temperature measurement pad 352b may be connected to a second temperature sensing resistor 361b through the upper metal layer 370.

The resistors 361b and 363a electrically connected to the temperature measurement pads 352 like this are temperature sensing resistors 361b and 363a which measure the temperature of a heat generation source of the semiconductor device 300. Specifically, as resistance values of the temperature sensing resistors 361b and 363a change according to the temperature of an active layer around a gate electrode 321 of a transistor 320, which is one of the main heat generation sources of the semiconductor device 300, the temperature may be measured. That is, the temperature sensing resistors 361b and 363a may provide resistance values that serve as a basis for calculating the temperature and temperature change of the transistor 320.

the temperature sensing resistors 361b and 363a are electrically connected while being disposed adjacent to the temperature measurement pads 352. Accordingly, anti-resonance resistors 361 or floating resistors 363 may serve as the temperature sensing resistors 361b and 363a according to the arrangement of the temperature measurement pads 352, and the number of temperature sensing resistors 361b and 363a may be one or more. Accordingly, the number of temperature measurement pads 352 may also be one or more. For example, when different temperature measurement pads 352 are connected to both terminals of a first floating resistor 363a, the first floating resistor 363a may function as the first temperature sensing resistor 363a. In some cases, even when a gate pad 351 is connected to one terminal of a second anti-resonance resistor 361b and a temperature measurement pad 352 is connected to the other terminal, the second anti-resonance resistor 361b may function as the second temperature sensing resistor 361b. That is, at least one gate pad 351 may also function as a temperature measurement pad 352.

Accordingly, the first temperature measurement pad 352a and the third temperature measurement pad 352c are electrically connected to the temperature sensing resistor 363a through the upper metal layer 370, and the second temperature measurement pad 352b and a second gate pad 351b are electrically connected to the second temperature sensing resistor 361b through the upper metal layer 370.

The temperature sensing resistors 361b and 363a are formed as thin film resistors or mesa resistors, and preferably, may be formed as thin film resistors. The temperature sensing resistors 361b and 363a each have a high temperature coefficient of resistivity (TCR). That is, a change in resistance values of the temperature sensing resistors 361b and 363a due to heat is large. The temperature sensing resistors 361b and 363a receive heat generated from at least one transistor 32 through the active layer 330.

The temperature measurement pads 352 may transmit a temperature measurement current to the temperature sensing resistors 361b and 363a through the upper metal layers 370 which come into contact with the temperature measurement pads 352. The temperature measurement current may be applied to the temperature measurement pads 352 from a terminal at the outside of the semiconductor device 300 which comes into contact with the temperature measurement pads 352.

Further, the temperature measurement pads 352 may receive temperature information of the temperature sensing resistors 361b and 363a or the transistor 320 through the upper metal layers 370. Here, the temperature information refers to electrical characteristics of the temperature sensing resistors 361b and 363a that change according to heat generated from the transistor 320. For example, the temperature information may be a current value, a voltage value, or a resistance value of the temperature sensing resistors 361b and 363a that change according to heat generated from the transistor 320.

That is, the temperature measurement pads 352 may cause the terminal at the outside of the semiconductor device 300 to measure a voltage applied to the temperature sensing resistors 361b and 363a by the temperature measurement current. Since a measurement device at the outside of the semiconductor device 300 may acquire values of currents flowing through the temperature sensing resistors 361b and 363a and values of voltages applied to the temperature sensing resistors 361b and 363a through the temperature measurement pads 352, resistance values of the temperature sensing resistors 361b and 363a may be calculated using Ohm's law.

That is, the temperature measurement pads 352 may be electrically connected to at least one temperature sensing resistor 361b and 363a through at least one upper metal layer 370, receive the temperature information through the at least one upper metal layer 370, and provide the temperature information to an external terminal in contact with the temperature measurement pads 352.

Accordingly, since the resistance values of the temperature sensing resistors 361b and 363a may be calculated, and thus, a change in temperature transmitted to the temperature sensing resistors 361b and 363a is calculated, a change in temperature of the transistor 320, which is a main heat generation source of the semiconductor device 300, may also be calculated. That is, since the temperature sensing resistors 361b and 363a receive heat generation of the transistor 320 through the active layer 330, the temperature of the temperature sensing resistors 361b and 363a may also change according to the temperature change of the transistor 320. In addition, as the temperature change of the temperature sensing resistors 361b and 363a is calculated based on the change in resistance values of the temperature sensing resistors 361b and 363a, the temperature change of the transistor 320 may also be calculated.

Further, according to the above-described embodiment, the temperature sensing resistors 361b and 363a are some of the plurality of resistors 360, and thus have the same arrangement positions and materials as the anti-resonance resistor 361 and the floating resistor 363. Accordingly, an additional manufacturing process need not be added to additionally dispose the temperature sensing resistors 361b and 363a in the semiconductor device 300 in which the anti-resonance resistors 361 are disposed. Accordingly, the second temperature sensing resistor 361b may quickly sense a change in temperature of the main heat generation source of the transistor 320 while suppressing the resonance of the transistor 320 in the semiconductor device 300 like the anti-resonance resistor 361. Further, the first temperature sensing resistor 363a may sense the change in temperature of the transistor 320 through the floating resistor 363, and accordingly, a circuit configuration of the semiconductor device 300 may be integrated and simplified. Furthermore, when the floating resistor 363 becomes the temperature sensing resistor 363a, since only one temperature measurement terminal is required, temperature measurement costs are reduced.

Further, the semiconductor device 300 according to an embodiment of the present disclosure may accurately measure a temperature of a maximum heat generation point of the semiconductor device 300 by measuring temperature through the second temperature sensing resistor 361b disposed adjacent to a transistor located at the center among the plurality of transistors 320.

Further, the semiconductor device 300 according to an embodiment of the present disclosure may measure a temperature of an outer region of the semiconductor device 300 by measuring temperature through the first temperature sensing resistor 363a disposed adjacent to side of the semiconductor device 300.

Further, the semiconductor device 300 according to an embodiment of the present disclosure may accurately monitor a heat dissipation state of the semiconductor device 300 by simultaneously measuring the temperature of the maximum heat generation point and the temperature of the outer region of the semiconductor device 300

Further, external air of the semiconductor device 300 is heated by operation of the semiconductor device 300, but has a temperature different from the temperature of the transistor 320 which is the main heat generation source of the semiconductor device 300. However, according to the above-described embodiment, since the temperature sensing resistors 361b and 363a are separated from the external air of the semiconductor device 300 by the upper metal layer 370, the temperature sensing resistors 361b and 363a may more accurately measure the temperature of the transistor 320.

Although the embodiments of the present invention have been described in more detail with reference to the accompanying drawings, the present invention is not necessarily limited to these embodiments, and may be variously modified without departing from the technical spirit of the present invention. Accordingly, the embodiments disclosed in the present invention are intended to not limit but to describe the technical spirit of the present invention, and the scope of the technical spirit of the present invention is not limited by these embodiments. Accordingly, the embodiments described above should be understood as being exemplary and not limiting in all aspects. The scope of the present invention should be understood by the following claims, and all technical spirit within the equivalent range should be understood as being within the scope of the present disclosure.

1. A semiconductor device comprising:
a semiconductor substrate;
a plurality of transistors disposed on the semiconductor substrate and each transistor including a gate electrode, a source electrode, and a drain electrode;
a plurality of gate pads disposed on the semiconductor substrate and disposed at an outside of the plurality of transistors;
a plurality of resistors disposed on the semiconductor substrate and electrically connected to at least one of the plurality of gate pads; and
a plurality of upper metal layers disposed on the semiconductor substrate and configured to come into contact with the plurality of resistors,
wherein at least one of the plurality of gate pads is electrically connected to the gate electrode of each of the plurality of transistors,
the plurality of gate pads are spaced apart from each other,
at least one of the plurality of resistors is an anti-resonance resistor, and
the anti-resonance resistor is configured to suppress resonance generated by operation of the plurality of transistors, is disposed between two gate pads and is electrically connected to at least one gate pad of the two gate pads through the upper metal layer.

2. The semiconductor device of claim 1, further comprising an active layer disposed between the semiconductor substrate and the transistors,
wherein the active layer is formed of a compound including Ga and N and has thermal conductivity.

3. The semiconductor device of claim 2, wherein the plurality of resistors are formed as one among thin film resistors and mesa resistors.

4. The semiconductor device of claim 3, further comprising at least one temperature measurement pad spaced apart from the plurality of gate pads,
wherein at least one of the plurality of resistors is a temperature sensing resistor for calculating a temperature change of the plurality of transistors,
wherein the at least one temperature measurement pad is electrically connected to the temperature sensing resistor through the plurality of upper metal layers, and is configured to provide a current value or a voltage value of the temperature sensing resistor to a terminal external to the semiconductor device.

5. The semiconductor device of claim 4, wherein the temperature sensing resistor is the anti-resonance resistor.

6. The semiconductor device of claim 4, further comprising an electrically opened floating resistor disposed on the semiconductor substrate,
wherein the floating resistor is electrically connected to the at least one temperature measurement pad and is a temperature sensing resistor for calculating a temperature change of) the plurality of transistors.
